(19) United States
(12) Patent Application Publication
(10) Pub. No.: US 2002/0157865 A1
(43) Pub. Date: Oct. 31, 2002

(54) Flexible flat circuitry with improved shielding

(76) Inventor: Atsuhito Noda, Tokyo (JP)

Correspondence Address: Thomas D. Paulius, Molex Incorporated, 2222 Wellington Court, Lisle, IL, 60532, US

(21) Appl. No.: 10/128,085

(22) Filed: Apr. 23, 2002

(30) Foreign Application Priority Data
Apr. 26, 2001 (JP) 2001-129126

(51) Int. Cl. H05K 1/11

(52) U.S. Cl. 174/261

(57) ABSTRACT

A FFC includes an insulating sheet having a first surface and a second surface. The FFC further has a plurality of first conductive groupings disposed on the first surface and extending in a longitudinal direction of the insulating sheet, each of the plurality of first conductive groupings includes a conductor disposed between a first ground and a second ground. The FFC further has a plurality of second conductive groupings disposed on the second surface and extending in a longitudinal direction of the insulating sheet, wherein each of the plurality of second conductive groupings includes a third ground. Moreover, each of the first conductive groupings is disposed at a first position relative to each of the second conductive groupings on the first surface and the second surface of the insulating sheet.

### BACKGROUND OF THE INVENTION

The present invention relates generally to a flexible flat circuit having improved electromagnetic shielding, and more particularly, to a flexible flat circuit having a defined relationship between signal patterns, ground patterns and connector contacts.

Flexible flat circuitry (“FFC”) is conventionally known and may include a plurality of signal patterns are arranged in a longitudinal direction on a first surface of a flexible insulating sheet and ground patterns for electromagnetic shielding are provided on the second surface of the insulating sheet. The ground patterns on the second surface of the insulating sheet may be configured so that the second surface, as a whole, is coated by a metal layer, such as a metal mesh for enhancing elasticity. The metal layer configuration is described in, for example, Japanese Utility Model Application Laid-Open No. SHO62-5417. The metal mesh configuration is described in, for example, Japanese Utility Model Application Laid-Open No. HEI10-112224.

As a result of miniaturization and higher performance requirements in various kinds electronic equipment, there is a demand to provide flexible flat circuits that can transmit more signals. In order to achieve a high density of signal patterns, the circuit has to have a high wiring density. If the spacing between the signal patterns is reduced, in order to obtain the high wiring density, impedance is degraded and cross-talk occurs. Japanese Utility Model Application Laid-Open No. SHO62-5417 discloses a circuit in which the signal patterns and the ground patterns are alternatively arranged in a staggered manner. Both end portions of each ground pattern are respectively arranged in a position that is flush or overlapped with the end portion of the ground pattern through the insulating sheet.

In signal cables, flat flexible circuitry, in which the signal pattern is highly concentrated, connectors are frequently used for connecting equipment or other cables to each other. The use of a connector facilitates the connection of multiple wires or electrical equipment and thereby enhances the reliability of the signal. In the cable described in Japanese Utility Model Application Laid-Open No. SHO62-5417, the signal patterns are provided on both surfaces of the insulating sheet. Therefore, contacts for the connector are necessary on both surfaces of the insulating sheet, which results in increased manufacturing costs and also affects the reliability of the connector. For instance, a connector having contacts that only engage one surface of the FFC cannot be used with such an FFC.

The above-described Utility Model application discloses FFC having signal patterns and ground patterns alternatively disposed on one surface of the insulating sheet and a solid ground pattern is provided across the other surface. In this case, it is necessary to electrically connect the ground patterns on one surface to the ground pattern on the other surface. Normally, through holes passing completely through the insulating sheet are provided and the conductive members are patterned for electrical connection of the ground patterns to each other. Unfortunately, this causes discontinuities (i.e., peaks and valleys) impedance. More specifically, there is a problem that the spacing between the signal patterns must be adjusted or a via hole must be changed.

Therefore, there exists a need for a flexible flat circuit achieving a higher level of wiring density, having signal patterns and ground patterns on one surface and a ground pattern on the other surface, to thereupon reduce impedance discontinuities and further enhance the shielding properties within the circuit.

### SUMMARY OF THE INVENTION

Accordingly, it is a general object of the present invention to provide an improved FFC construction that has better shielding properties.

Another object of the present invention is to provide an FFC construction in which signal and ground traces are arranged thereupon in groupings on opposite sides of a supporting base sheet.

A still further object of the present invention is to provide an extent of FFC having a base insulative sheet that supports a plurality of conductive traces thereupon and on opposite sides of the base sheet, the groupings on one side of the base sheet including signal traces and ground traces, the signal traces being disposed between a pair of ground traces, and the groupings on the other side of the base sheet including at least a large ground trace, the width of the large ground traces being greater than the width of the combined grouping of the signal and ground traces on the first side of the base sheet.

The present invention accomplishes these and other objects by way of its structure. the present invention provides an extent of FFC having an insulating, or base, sheet with first and second opposing surfaces. The FFC has a plurality of first conductive groupings disposed on the first surface, which extend longitudinally, or lengthwise, of the base sheet. Each of the first conductive groupings include signal patterns, or traces, disposed between first and second ground ground patterns, or traces. The FFC further has a plurality of second conductive groupings disposed on the second (opposite) surface of the base sheet which also extend longitudinally, and each second conductive grouping includes a third ground pattern, or trace.

In one embodiment, each of the first conductive groupings has a first width and each of the plurality of second conductive groupings has a second width and the second width is greater than the first width. Within the first conductive groupings, each signal conductor is spaced from the first and second ground conductors by a distance alpha (a ), and the first conductive groupings are spaced apart from each other by a distance of beta (β). On the second surface of the circuit, the second conductive groupings are spaced apart from each other a distance of gamma (?), and the distance gamma is less than the distances alpha and beta. Furthermore, the plurality of first conductive groupings are in opposition with the plurality of second conductive groupings on opposing sides of the FFC, wherein the space defined by the distance gamma is in opposition to the space defined by the distance beta.

The FFC further includes a coating layer disposed on the plurality of first conductive groupings, wherein the coating layer is formed with a low inductive insulator with elasticity. The circuit also contains a magnetic shield layer disposed on the coating layer. Moreover, the plurality of first conductive groupings may be in electrical contact with a plurality of terminals of a connector.

These and other objects, features and advantages of the present invention will be clearly understood through a consideration of the following detailed description.

### BRIEF DESCRIPTION OF THE DRAWINGS

In the course of this detailed description, the reference will be frequently made to the attached drawings in which:

FIG. 1 is a perspective view of an extent of flexible flat circuitry constructed in accordance with the principles of the present invention;

FIG. 2 is a cross-sectional view of the FFC of FIG. 1 taken along line II-II thereof;

FIG. 3 is a graph showing a relationship between an impedance and a shape parameter of the FFC of FIG. 1;

FIG. 4 is a graph showing a relationship between an impedance and a shaped parameter of the FFC of FIG. 1;

FIG. 5 is a side view showing an electromagnetic field analysis of the FFC of FIG. 1;

FIG. 6 is a cross-sectional view of the FFC of FIG. 1 having a coating layer and an electromagnetic shield layer disposed thereon;

FIG. 7 is a side view showing an electromagnetic field analysis of the FFC of FIG. 6;

FIG. 8 is a cross-sectional view of a second embodiment of an extent of FFC constructed in accordance with the principles of the present invention;

FIG. 9 is a side view showing an electromagnetic field analysis of the FFC of FIG. 8;

FIG. 10 is a cross-sectional view of the FFC of FIG. 8 having a coating layer and a electromagnetic shield layer disposed thereon;

FIG. 11 is a side view showing an electromagnetic field analysis of the FFC of FIG. 10; and,

FIG. 12 is a cross-sectional view of a connector that may be connected to the FFC.

### DETAILED DESCRIPTION OF THE PRESENT INVENTION

FIG. 1 illustrates a flexible flat circuit (“FFC”) 1 which includes a flexible insulating, or base sheet 2, having plurality of a first conductive groupings 3 on a first side 4 thereof and a plurality of second conductive groupings 5 on a second side 6 thereof. As illustrated in FIG. 1, the first conductive groupings 3 are composed of three separate elements, a first ground pattern or trace 7, a second ground pattern or trace 8 and a signal pattern or trace 9. The FFC 1 has a plurality of these first conductive groupings disposed on its first side and these groupings are equally spaced apart from each other.

FIG. 1 also illustrates the second conductive groupings 5 disposed on the second surface 6 of the FFC. These second conductive groupings 5 contain a third ground 10 that extends longitudinally on the FFC 1. Similar to the first conductive groupings 3, the second conductive groupings 5 are equally spaced apart from each other on the base sheet second surface 6.

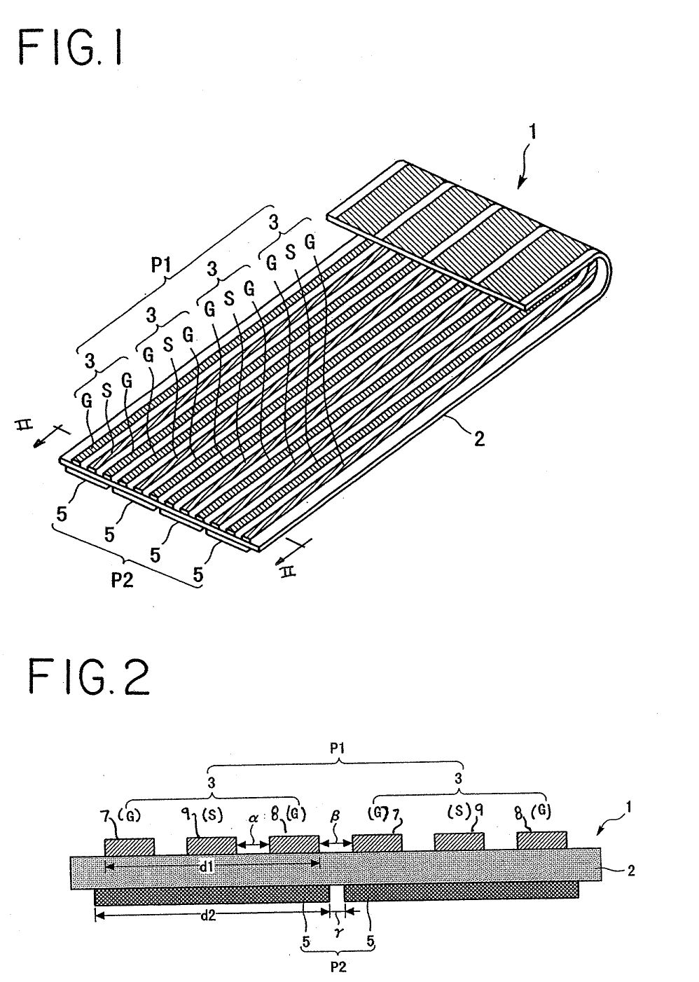

FIG. 2 illustrates a cross-sectional view of the FFC of FIG. 1 taken along line II-II in FIG. 1. This view more clearly illustrates the dimensions of the insulating sheet 2, the first conductive groupings 3 and the second conductive groupings 5. Within the first conductive groupings, the distance between the conductor 9 and either the first ground 7 or the second ground 8 is a distance alpha (a ). The distance between each of the plurality of first conductive groupings 3 is a distance of beta (β). Also illustrated in FIG. 2, the distance between the second conductive groupings 5 is a distance of gamma (?).

It also can be seen that each of the first conductive groupings 3, consisting of the two grounds and a conductor centrally disposed therebetween, has a width of d1, referred to herein as a first width. Each of the second conductive groupings 5 has a width of d2, referred to herein as a second width. Although FIG. 1 illustrates four such groupings 3, 5 and FIG. 2 illustrates two conductive groupings 3, 5, the number of conductive groupings shown is for illustrative purposes only and is not intended to be limiting.

The dimensions of the spacing of alpha, beta and gamma a , β and ? may be adjusted to provide an increased level of electrical isolation and thereby reduce the amount of impedance or cross-talk within the FFC. Also, the signal conductor 9, the first ground 7, the second ground 8 and the third ground 10 may be made of a metal, such as silver, copper, gold or any other suitable metal, which is superior in conductivity. These signal patterns may be formed by using a conventional technique such as wire bonding, photo-resist or other etching, or any other technique as recognized by one skilled in the art.

The FFC has a structure wherein the signal conductor 9 of the first conductive grouping 3 is provided on only one surface and the second conductive grouping 5 provided on the other surface, separated by the insulating sheet 2. No electricity flows through the second conductive groupings 5, more specifically no electricity flows through the third ground 10. Therefore, electromagnetic shielding properties, through a coupling effect, are achieved by the position of the first ground 7 and the second ground 8 on both sides of the signal conductor 9 and the third ground 10 disposed on the second surface

It should also be noted that the second width, d2, the width of the second conductive grouping 5 is greater than the first width, d1, the width of the first conductive grouping 3, thereby enhancing the coupling effect between the conductive groupings, 3 and 5. In one embodiment, the interval a between the signal conductor 9 and the grounds 7 and 8 and the interval beta between the adjacent first conductive groupings 3 are the same distance.

Furthermore, the width of the signal conductor 9 and the width of the first and second grounds 7, 8 are substantially equal. Also, the distance defined by the spacing dimension of ? is less than the distance defined by the spacing of a and β. The position of the interval gamma between the second conductive grouping 5 is aligned with the interval 13 between the first conductive grouping 3 to further prevent any cross-talk between the first conductive grouping 3.

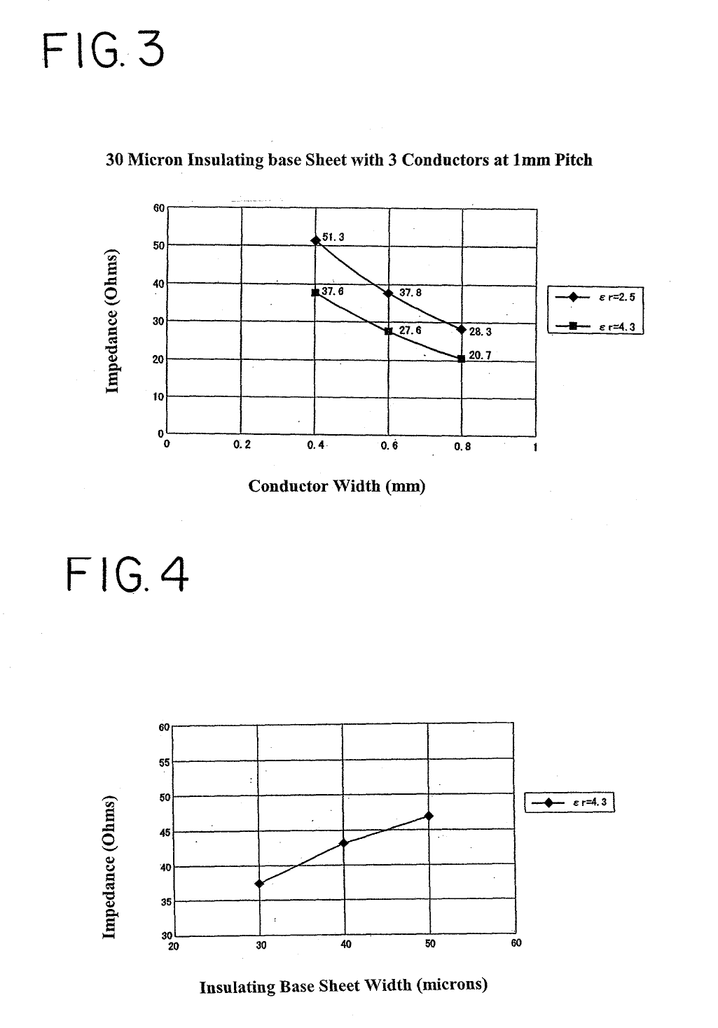

FIG. 3 is a graph showing the relationship between an impedance and a shape, or width, parameter, namely the width of the first ground 7, the second group 8 and the signal conductor 9, which is posted on the X-axis of the graph (in millimeters) and the impedance (in ohms) which is posted on the Y-axis. FIG. 3 illustrates two separate measurements based on different dielectric constants in the insulating base sheet which is noted by diamonds in the first measurement noted by diamonds, with a relative dielectric constant, or permitivity, for the insulating base sheet of er=2.5 (in farads/meter), and in the second measurement noted by squares, with a permitivity of the base sheet er=4.3. Moreover, the graph of FIG. 3 illustrates the relationship based on the insulating sheet 2 having a thickness of 30 microns and the distances a and 13 are approximately 1 mm. This graph illustrates that the larger the width of the signal conductive member, the lower the impedance. Also, under the same conditions, it is shown that the larger the(pernitivity), er, the smaller the impedance becomes.

FIG. 4 is a graph showing the relationship between an impedance and the thickness of insulating member where impedance (in ohms) is displayed on the Y-axis and the thickness of the insulating member (in microns) is displayed on the X-axis, and the permitivity is er=4.3.

FIG. 4 illustrates that the greater the thickness of the insulating or base sheet, in microns, the greater the impedance. An insulating member having a thickness of 50 microns has an impedance of approximately 46 ohms.

FIG. 5 shows the co-planar electromagnetic analysis when an electric signal passes through the first conductor grouping 3. As illustrated in FIG. 5, the first ground 7 and the second ground 8 effectively isolate the electric field generated by the conductor 9, in conjunction with the third ground, not shown. Thus, the electrical signal, which passes through the conductor, is effectively shielded. As illustrated in FIGS. 1 and 2, a plurality of first conductive groupings 3 are aligned along the first surface of the insulator and a plurality of second conductive groupings 5 are aligned along the second surface of the insulating sheet. FIG. 5 illustrates how the conductors 9 within the plurality of the first conductive groupings 5 are shielded from each other on the FFC of the present invention.

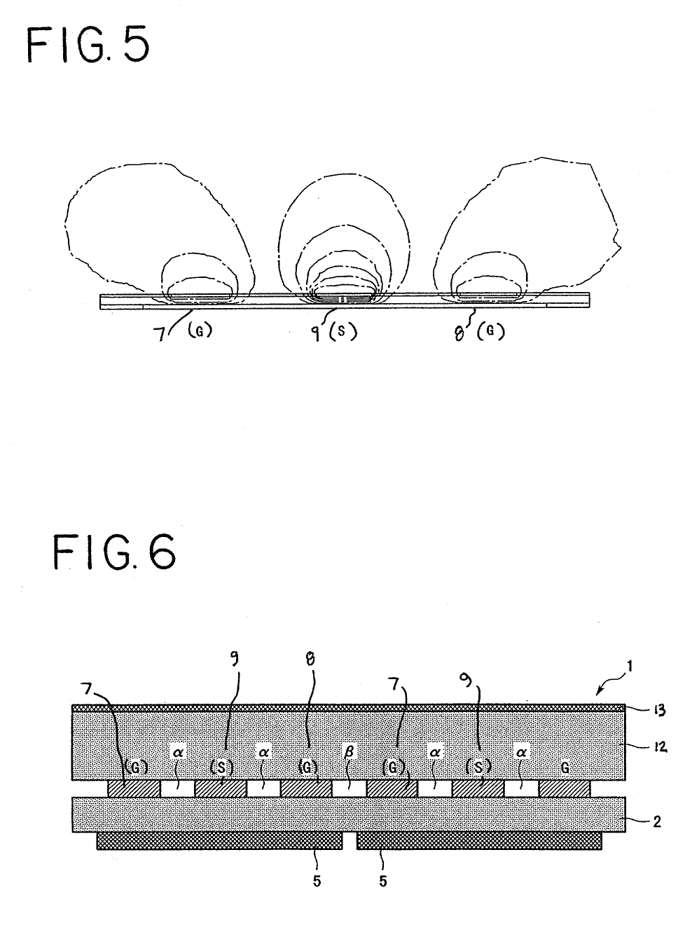

FIG. 6 illustrates the flexible flat circuit of FIG. 2 having a coating layer 12 disposed over the first conductor groupings 3 on the first surface 4 of the insulating material 2. In the preferred embodiment, the coating layer 12 is composed of a flexible, low permitivity insulating material. An electromagnetic shielding layer 13 is disposed on top of the coating layer 12. This may be done by applying a metal plating film to the surface of the coating layer 12, or by bonding a thin film made of magnetic material, such as, Maxcell tape or amorphous tape, onto the coating layer 12.

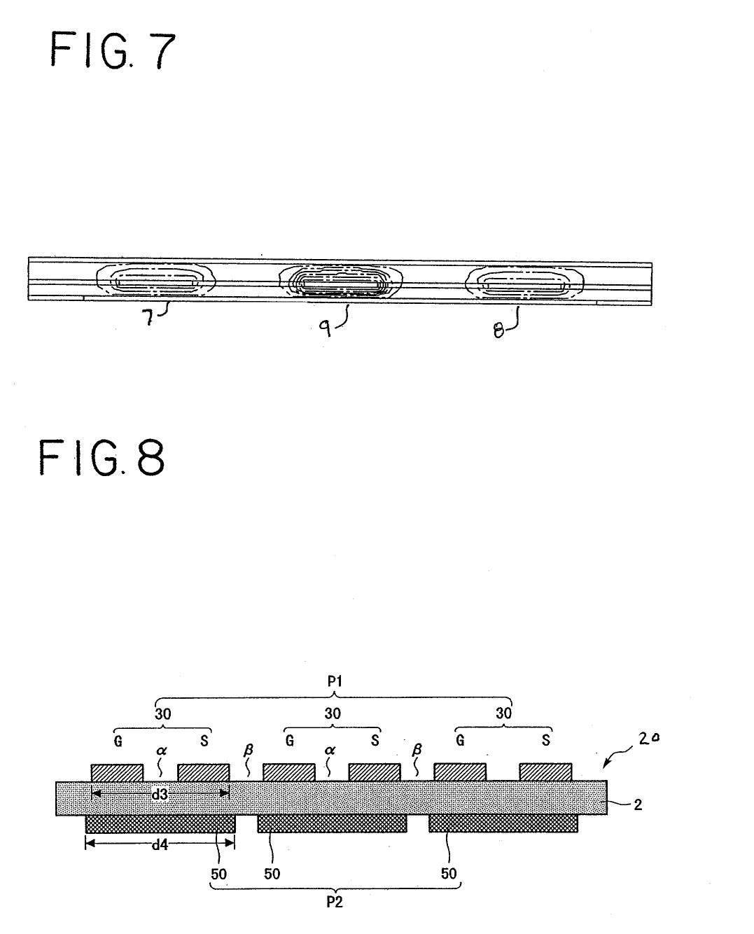

In another embodiment, not illustrated, the coating layer 12 having the electromagnetic shield layer 13 may also be disposed on second conductive groupings 5 so as the cover the top and bottom surfaces of the FFC and so “enclose” the conductive groupings 3 and 5. The coating layer 12 and the electromagnetic shield layer 13 may be created in the same fashion and composed of the same material as illustrated in FIG. 6. Thereupon, the same shielding effect provided to the first conductive groupings 3, as illustrated below in FIG. 7, may be provided to the second conductive groupings 5.

By utilizing the coating layer 12, it provides an extra layer of protection for the conductor 9, the first ground 7 and the second ground 8. Also, the electromagnetic shielding layer 13 protects the coating layer 12 and also therein further enhances the shielding effects for the plurality of first conductive groupings 3.

FIG. 7 shows an electromagnetic field analysis of the FFC of FIG. 6 having the coating layer 12 and the electromagnetic shielding layer 13 disposed thereon. FIG. 7 illustrates the electromagnetic shielding effect that is exhibited due to the electromagnetic shield layer 13. Thereby, the embodiment of FIG. 6 provides noise-proof performance for a densely populated FFC having a plurality of first and second conductive groupings.

FIG. 8 illustrates another embodiment of the invention, such as a FFC 20 having the insulating sheet 2 with opposing first and second surfaces 4 and 6. A plurality of first conductive groupings 30 are disposed on the first surface 4 that longitudinally extend for the length of the insulating sheet 2. Each of the plurality of first conductive groupings 30 includes a conductor 32 and a ground 34. The FFC 20 further includes a plurality of second conductive groupings 50 disposed on the second surface 6 of the insulating sheet 2, and they also longitudinally extend on the insulating sheet 2, wherein the second conductive groupings 50 act as a ground for the overall FFC. Furthermore, each of the first conductive patterns 30 and the second conductive patterns 50 are disposed at a first position and a second position relative to each other on the insulating sheet 2.

As illustrated in FIG. 8, the conductor 32 and the ground 34 are disposed from each other by a distance a. The plurality of first conductive groupings are disposed from each other by a distance β. And the plurality of second conductive groupings are disposed from each other by a distance ?. Each of the plurality of first conductive groupings 30 has a first width, d3, and each of the second conductive groupings 50 has a second width, d4, wherein the second width, d4, is greater than the first width, d3. Also, the distance β is greater than the distance ? wherein the spacing defined by the distance ? is disposed within, on opposing side of the insulating sheet 2, the distance β.

The plurality of grounds 34 within the plurality of first conductive groupings 30 and the second conductive groupings 50 are insulated from each other by the insulating sheet 2. The interval a between the conductor 32 and the ground 34 is smaller than the interval β between the adjacent conductive groupings 30.

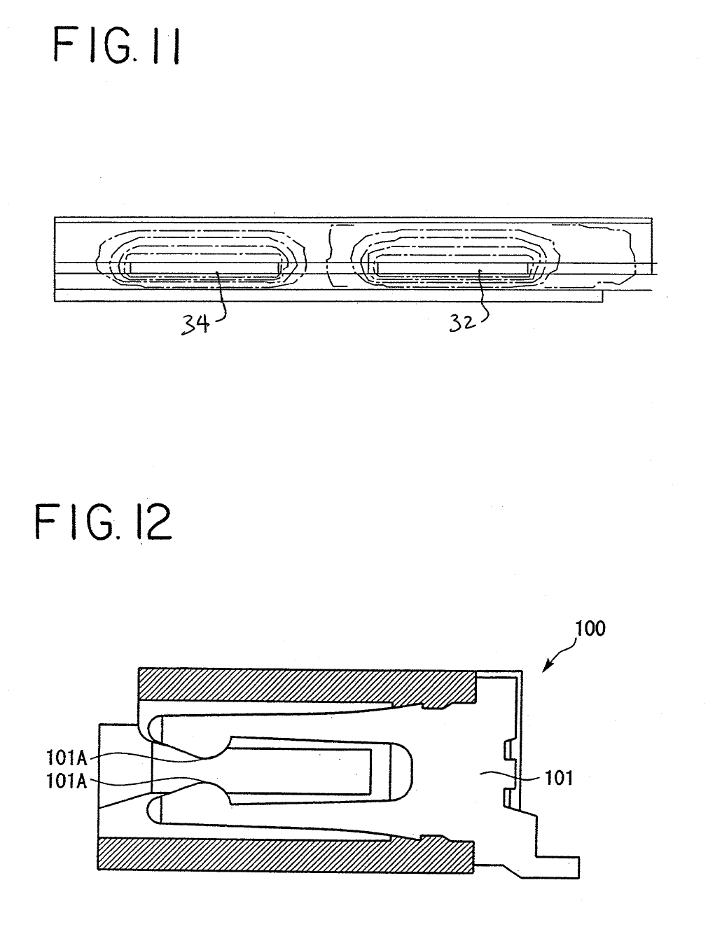

In this embodiment, it is possible to form the contacts to a connector, as discussed below with reference to FIG. 12, on one surface of the circuit to thereby remove elements (e.g., pitch change of the pad portions or via holes) that cause any turbulence in impedance. Furthermore, the plurality of grounds 34 are provided on both sides of the conductors 32 and the second conductive groupings 50 are provided on the other surface to thereby surround the conductor 32 and make it possible to enhance the shielding property of the FFC 20. In the circuit 20 according to this embodiment, it is possible to increase the number of the conductors 32 in comparison with the FFC of FIG. 1 and to substantially enhance the wiring density, while maintaining noise-proof performance.

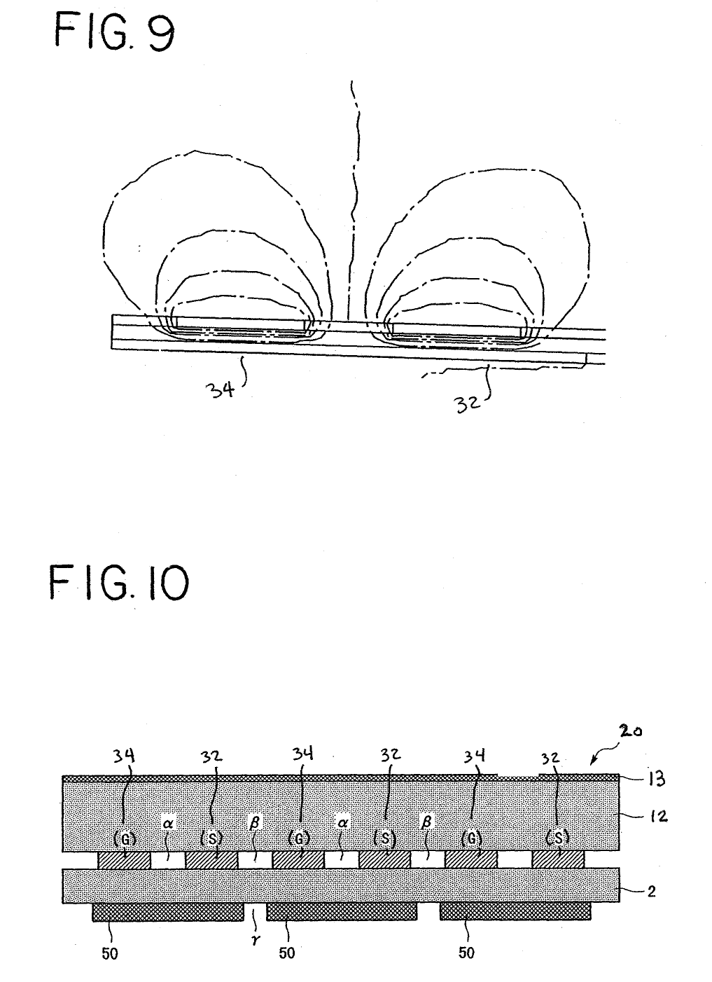

FIG. 9 illustrates a co-planar electromagnetic analysis of the FFC of FIG. 8. Similar to the co-planar electromagnetic analysis of FIG. 5, the shielding properties of the first and second conductive groupings is visible. The electromagnetic field generated by the conductor and the field generated by the ground do not intersect, therefore there is no degradation of the signal passing through the conductor 32.

FIG. 10 illustrates another embodiment of the of the FFC of FIG. 8, having the coating layer 12 and the electromagnetic shielding layer 13 disposed thereon. The embodiment of FIG. 10 is similar to the embodiment of FIG. 6, except for the composition and orientation of the first conductive groupings 30 and the second conductive groupings 50. Similar to the embodiment of FIG. 6, the coating layer 12 is composed of a low inductivity insulating material, wherein the shield is composed of a metal. Furthermore, the coating layer 12 maybe bonded on the first conductive groupings 30 and the electromagnetic shield layer 13 may be formed by applying, for example, a metal plating film on the surface of the coating layer 12. Furthermore, it is possible to adopt a structure in which a sheet material having a film made of magnetic material, for example, Maxcell tape or amorphous tape is bonded onto either one surface or both surfaces of the circuit 20.

FIG. 11 illustrates an electromagnetic field analysis result of the flexible flat circuit 20 of FIG. 10. Similar to the analysis of FIG. 9, the conductor 32 is shielded from the ground 34. Moreover, the shield 13 disposed on the coating layer 12 contains the electromagnetic field. Thus, the flexible flat circuit 20 in accordance with FIG. 10 provides proper shielding of the conductor signal to allow a higher signal density on the circuit.

FIG. 12 illustrates a connector assembly 100 having a plurality of contact portions 101A disposed within a terminal 101 of the connector. The FFC 1 or 20 may be disposed within the connector assembly 100 wherein the first conductive groupings disposed on the first surface of the insulating material may contactingly engage the upper contact portion 110A and the second conductive groupings disposed on the second surface of the insulating material may contactingly engage the lower contact portion 101A.

The connector assembly 100 may thereupon, in accordance with known connector assembly technology, transmit the signals across the FFC, whereby the FFC allows a higher density of conductors with a reduction in cross-talk and impedance therein.

While the preferred embodiment, and further embodiments therein, have been shown and described, it will be apparent to those skilled in the art that changes and modifications may be made therein without departing from the spirit of the invention, the scope of which is defined by the appended claims.

What is claimed is:

1. A flat flexible circuitry comprising: an insulating sheet having a first surface and a second surface;
a plurality of first conductive groupings disposed on the first surface and extending in a longitudinal direction of the insulating sheet, each of the plurality of first conductive groupings includes a signal conductor disposed between first and second grounds;
a plurality of second conductive groupings disposed on the second surface and extending in the longitudinal direction of the insulating sheet, wherein each of the plurality of second conductive groupings includes a third ground; and,
wherein each of the first conductive groupings is disposed at a first position on the first surface relative to each of the second conductive groupings on the second surface of said insulating sheet.

2. The flexible flat circuitry of claim 1, wherein each of said first conductive groupings has a first width and each of said second conductive groupings has a second width which is greater than the first width.

3. The flexible flat circuitry of claim 2 wherein each signal conductor of said first conductive groupings is spaced apart from said first and second grounds by a distance a, each of said first conductive groupings is spaced apart by a distance β and each of said second conductive groupings is spaced apart by a distance ?, the distance ? being less than either of the distances a and β.

4. The flexible flat circuitry of claim 5 wherein said second conductive groupings on said second surface are arranged in opposition to said first conductive groupings on said first surface so that the distance ? opposes the distance β.

5. The flexible flat circuitry of claim 1, wherein said signal conductor and said first and second grounds have equal widths.

6. The flexible flat circuit of claim 1, wherein said the first ground, the second ground, the third ground and the conductor are insulated from each other by the flexible insulating sheet.

7. The flexible flat circuitry of claim 1, further including a coating layer disposed over said first conductive groupings, the coating layer being formed of a flexible, low permitivity insulative material.

8. The flexible flat circuitry of claim 7, further including an electromagnetic shielding layer disposed on said coating layer.

9. The flexible flat circuitry of claim 1, wherein said first conductive groupings are in electrical contact with a plurality of terminals of a connector.

10. An extent of flat flexible circuitry (“FFC”) comprising: an insulating base sheet having first and second opposing surfaces; a plurality of first groupings of conductors disposed on the first surface, each of the first conductive groupings including a signal conductor and at least one ground conductor, the signal and ground conductors extending longitudinally upon said insulating base sheet first surface; a plurality of second conductive groupings disposed on said insulating base second surface and extending longitudinally upon said insulating base sheet second surface; and, wherein each of said first conductive groupings is disposed at a first position on said first surface relative to the each of the second conductive groupings is disposed on said second surface of said insulating base sheet.

11. The FFC extent of claim 10, wherein each of said first conductive groupings has a first width and each of said second conductive groupings has a second width that is greater than the first width.

12. The FFC extent of claim 13, wherein each of said signal conductors of said first conductive groupings is spaced apart from said ground conductors thereof by a distance a, each of said first conductive groupings is spaced apart from each other by a distance β, and each of the plurality of second conductive groupings is spaced apart by a distance?, and wherein the distance ? is less than either of the distances a and β, and wherein said distances a and β are approximately equal.

13. The FFC extent of claim 12, wherein said first and second conductive groupings are insulated from each other by said insulating base sheet, said FFC further including a flexible coating layer formed from a low dielectric constant insulator, and an electromagnetic shield layer disposed upon said coating layer.

15. The FFC extent of claim 13, wherein said first conductive groupings includes contact portions for mating with opposing terminals of a connector.

16. A flat flexible circuit comprising:
an elongated base sheet having a predetermined length and width, the base sheet including opposing top and bottom surfaces, the top and bottom surface including a plurality of conductive traces that extend lengthwise along said base sheet top and bottom surfaces;
said traces being arranged in first conductive groupings on said base sheet first surface and in second conductive groupings disposed on said base sheet second surface and extending in the longitudinal direction of said base sheet, each of said first conductive groupings including a signal trace and at least one ground trace and each of said second conductive groupings including a single ground trace, each of said first conductive groupings being disposed at a first position on the first surface in opposition to each of said second conductive groupings on said second surface of said base sheet;
and each of said first conductive groupings having a first width and each of said second conductive groupings having a second width that is greater than the first width, said signal trace being spaced from said at least one ground trace by a distance a, said first conductive groupings being spaced apart by a distance β, and each of said second conductive groupings being spaced apart by a distance?, and wherein the distance ? is less than either of the distances a and β.
